(19) United States
(12) Patent Application Publication
(10) Pub. No.: US 2026/0361051 A1
(43) Pub. Date: Nov. 12, 2026

(54) METHOD FOR DRIVING LASER, LASER, COMPUTER STORAGE MEDIUM, AND ELECTRONIC DEVICE

(71) Applicant: Shenzhen Creality 3D Technology Co., Ltd., Shenzhen (CN)

(72) Inventors: Huilin LIU, Shenzhen (CN); Mingwen LI, Shenzhen (CN); Fayang CAO, Shenzhen (CN)

(21) Appl. No.: 19/132,037

(22) PCT Filed: Jun. 29, 2023
(86) PCT No.: PCT/CN2023/104103

§ 371 Date: May 22, 2025

(30) Foreign Application Priority Data
Dec. 21, 2022 (CN) 202211651995.9

(51) Int. Cl. H01S 5/042

(52) U.S. Cl. CPC H01S 5/042

(57) ABSTRACT

The present application provides a method for driving a laser, the laser, a computer storage medium, and an electronic device. The laser includes a plurality of light sources with different powers, the method includes: determining an operating mode of the laser in accordance with mode selection information; determining an output light power corresponding to the operating mode of the laser, and selecting one or more objective light sources from the plurality of light sources in accordance with the output light power corresponding to the operating mode of the laser; and driving the one or more objective light sources to emit light.

### TECHNICAL FIELD

This application relates to the field of laser engraving technologies, and specifically, to a method for driving a laser, the laser, a computer storage medium, and an electronic device.

### BACKGROUND

At present, users have strong expectations for laser engraving machines to achieve stronger cutting capabilities. Low-power laser modules are only suitable for engraving scenarios and not for broad cutting scenarios, which cannot meet user needs, and being gradually eliminated from the market.

In order to meet the needs of users for cutting ability, a power of a laser diode (LD) light source module of the current laser engraving machines is designed larger and larger. Because of the limited power of a single semiconductor laser, an incoherent spatial grouping method may be commonly used to accumulate powers of a plurality of LD light sources to achieve a power required by the LD light source module. The current laser module adopts a series design of LD light sources with the same power to achieve a power superposition. Although the power meets the cutting needs, because of its series drive design, the LD light sources must work at the same time, a light spot of the LD light source module is formed based on a plurality of light source spots superposing, so a size of the light spot is large which affects thicknesses of engraving lines, and decreases engraving effect.

### SUMMARY

Accordingly, this application provides a method for driving a laser, the laser, a computer storage medium, and an electronic device, which is capable of switching between different operating modes, and allow the laser to be applied to different scenarios.

First aspect of this application provides the method for driving the laser, the laser includes a plurality of light sources with different powers, the method includes: determining an operating mode of the laser according to mode selection information; determining an output light power corresponding to the operating mode of the laser, and selecting an objective light source with the same power as the output light power from the plurality of light sources; and driving the objective light source to emit light.

With respect to the prior technology, the embodiments of this application have at least the following advantages: the laser is formed by the plurality of light sources with different powers, by determining the operation mode of the laser to determine the output light power corresponding to the operation mode, a laser machine is capable of setting different output light power by switching different operation modes, then the laser is capable of being applied to different scenarios, such as engraving scenarios, cutting scenarios, etc., achieving best engraving and cutting effects in different scenarios, and improving a practicality of the laser.

In some possible implementation embodiments, the operating mode of the laser includes a low power operating mode, a high power operation mode, and a maximum power operation mode, the method of determining the output light power corresponding to the operating mode of the laser includes: determining the output light power as a first power in response to the operating mode of the laser being the low power operating mode; determining the output light power as a second power in response to the operating mode of the laser being the high power operating mode; and determining the output light power as a third power in response to the operating mode of the laser being the maximum power operating mode; the first power is less than the second power and the third power is equivalent to a sum of the first power and the second power.

By adopting these embodiments, a type of feasible operation modes of the laser is achieved.

In some possible implementation embodiments, the plurality of light sources include a first light source with the first power and a second t light source with the second power, the method of driving the objective light source to emit light includes: driving the first light source to emit light in response to the operating mode of the laser being the low power operating mode; driving the second light source to emit light in response to the operating mode of the laser being the high power operating mode; and driving the first light source and the second light source to emit light in response to the operating mode of the laser being the maximum power operating mode.

By adopting these embodiments, a feasible way to drive the plurality of light sources corresponding to the type of operating modes is realized.

In some possible implementation embodiments, the laser further includes a first driving circuit and a second driving circuit, the first driving circuit drives the first light source to emit light when receiving a high level output light signal, and the second driving circuit drives the second light source to emit light when receiving the high level output light signal; the method of driving the first light source to emit light in response to the operating mode of the laser being the low power operating mode includes: sending the high level output light signal to the first drive circuit and the second drive circuit in response to the operating mode of the laser being the low power operating mode; and controlling the high level output light signal sent to the second driving circuit from a high level to a low level.

By adopting these embodiments, a drive mode of light sources in a low-power operation mode is realized.

In some possible implementation embodiments, the method of driving the second light source to emit light in response to the operating mode of the laser being the high power operating mode includes: sending the high level output light signal to the first drive circuit and the second drive circuit in response to the operating mode of the laser being the high power operating mode; and controlling the high level output light signal sent to the first driving circuit from the high level to the low level.

By adopting these embodiments, a drive mode of light sources in a high-power operation mode is realized.

In some possible implementation embodiments, the method of driving the first light source and the second light source to emit light in response to the operating mode of the laser being the maximum power operating mode includes: sending the high level output light signal to the first drive circuit and the second drive circuit in response to the operating mode of the laser being the maximum power operating mode.

By adopting these embodiments, a drive mode of light sources in a maximum-power operation mode is realized.

In some possible implementation embodiments, the method of determining the operating mode of the laser according to the mode selection information includes: determining the operating mode of the laser according to key operation information of a user.

Second aspect of this application provides a laser, the laser includes a light source module, a microcontroller module, and an operation mode determination module; the light source module includes a plurality of light sources with different powers; the operation mode determination module is configured to determine an operating mode of the laser according to mode selection information; the microcontroller module is configured to determine an output light power corresponding to the operating mode of the laser, select an objective light source with the same power as the output light power from the light source module, and drive the objective light source to emit light.

Third aspect of this application provides a computer storage medium, the computer storage medium stores computer instructions, when the computer instructions run on an electronic device, the electronic device is caused to execute the above-mentioned method for driving the laser.

Fourth aspect of this application provides an electronic device, the electronic device includes a processor and a data storage, the data storage is configured to store instructions, the processor is configured to call the instructions stored in the data storage, to cause the electronic device to execute the above-mentioned method for driving the laser.

It is understood that the laser provided by the second aspect, the computer storage medium provided by the third aspect, and the electronic equipment provided by the fourth aspect, all correspond to the method provided by the first aspect, so beneficial effects that is capable of being achieved can be referred to a beneficial effect of the method provided by the first aspect, which will not be repeated herein.

### BRIEF DESCRIPTION OF DRAWINGS

FIG. 1 is a flowchart of a method for driving a laser according to an embodiment of the present application;

FIG. 2 is a schematic diagram of switching operation modes of the laser according to an embodiment of the present application;

FIG. 3 is a schematic diagram of spot sizes of the laser in three operating modes according to an embodiment of the present application;

FIG. 4 is a schematic structural diagram of a spatial combination of the laser according to an embodiment of the present application;

FIG. 5 a flowchart of a method for driving the laser according to another embodiment of the present application;

FIG. 6 is a schematic diagram of a driving method of the laser in a low-power operating mode according to an embodiment of the present application;

FIG. 7 is a schematic diagram of a driving method of the laser in a high-power operating mode according to an embodiment of the present application;

FIG. 8 is a schematic diagram of a driving method of the laser in a maximum-power operating mode according to an embodiment of the present application;

FIG. 9 is a schematic module diagram of the laser according to an embodiment of the present application;

FIG. 10 is a schematic structural diagram of an electronic device according to an embodiment of the present application.

### DESCRIPTION OF EMBODIMENTS

In order to more clearly understand the above purposes, features and advantages of the present application, the present application is described in detail below in conjunction with the drawings and the description of embodiments. It is understood that, embodiments of the present application and features in the embodiments may be combined with each other without conflict.

In the following description, many specific details are described in order to fully understand the present application, the described embodiments are only part of the present application, not all embodiments.

Unless otherwise defined, all technical and scientific terms used herein have the same meaning as those commonly understood by those skilled in the technical art of the present application. The terms used herein in the description of the present application are only for a purpose of describing the embodiments, and are not intended to limit the present application.

It should be further noted that, the term “including”, “comprising” or any other variation thereof is intended to cover non-exclusive inclusions, so that a process, a method, an article or an apparatus including a series of elements includes not only those elements, but also includes other elements not expressly listed, or also includes elements inherent in such process, method, article or device. Without further restrictions, an element limited by the statement “including a . . . ” does not exclude ab existence of another identical element in the process, method, article or apparatus including the element.

In the present application, “at least one” refers to one or more, “multiple” refers to two or more than two. “and/or”, describing the association relationship of the associated object, indicates that there may be three relationships, for example, A and/or B may mean: the existence of A alone, the existence of A and B at the same time, the existence of B alone, where A, B can be singular or plural. The terms “first”, “second”, “third”, “fourth” etc. (if exist) in the embodiments, claims, and drawings of the present application are used to distinguish similar objects, and are not used to describe a specific order or sequence.

In an embodiment of the present application, the words “for example” or “such as” are used to indicate as examples, illustrations or illustrations. Any embodiment or design described as “for example” or “such as” of the present application shall not be construed as being exemplary or more advantageous than other embodiments or designs. The use of words such as “for example” or “such as” is intended to present a concept in a concrete way.

In order to facilitate the embodiments, some concepts related to the embodiments of the present application are given exemplary descriptions for reference.

Lasers are devices that is capable of emitting laser, the lasers can be divided into four categories according to working mediums: gas lasers, solid lasers, semiconductor lasers, and dye lasers. The light source of the lasers is laser diode (LD) light source, a physical structure of the LD is to place a layer of light-active semiconductor between internodes of a light emitting diode, and a end surface of the LD has a partial reflection function after polishing to form a light resonator.

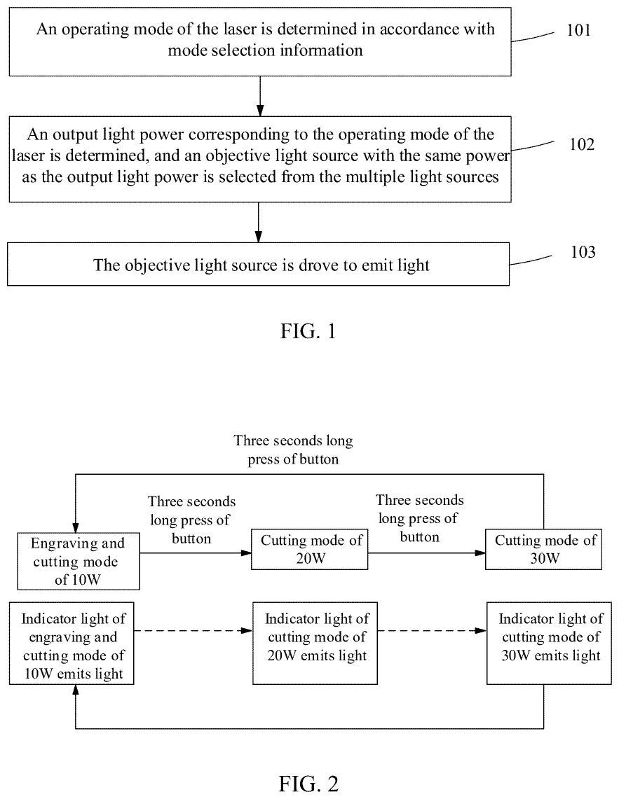

As shown in FIG. 1, it is a flowchart of a method for driving the laser according to an embodiment of the present application. The present embodiment can be applied to the laser side, the laser includes a plurality of light sources with different powers, as shown in FIG. 1, the method includes the following blocks.

In block 101, an operating mode of the laser is determined according to mode selection information.

In some embodiments, the operating mode of the laser can be determined by the following way: the operating mode of the laser is determined according to key operation information of a user.

In order to facilitate the embodiments, combining FIG. 2 to illustrate how the user can switch operation modes of the laser through a key operation.

As shown in FIG. 2, it is a diagram of switching operation modes of the laser. The user can select the operating mode of the laser via a button on the laser. A microcontroller equipped with the laser switches the operation mode of the laser according to the key operation information of the user. The microcontroller switches the current operation mode of the laser if detecting a three seconds long press of the button every time; a switching order of the laser includes a engraving and cutting mode of 10 W->a cutting mode of 20 W->a cutting mode of 30 W. A mode indicator formed by light-emitting diodes (LEDs) equipped with the laser indicates the current operating mode of the laser.

It is understood that the method for switching the operation mode of the laser is not limited to the above described, a plurality of buttons can be set, and different buttons correspond to different operation modes, etc. The present embodiment does not limit how to determine the operation mode of the laser, and can be set and adjusted according to actual requirements.

In block 102, an output light power corresponding to the operating mode of the laser is determined, and an objective light source with the same power as the output light power is selected from the plurality of light sources.

In block 103, the objective light source is driven to emit light.

In some embodiments, the operating mode of the laser includes a low power operating mode, a high power operation mode, and a maximum power operation mode. A method of determining the output light power corresponding to the operating mode of the laser may include: determining the output light power as a first power in response to the operating mode of the laser being the low power operating mode; determining the output light power as a second power in response to the operating mode of the laser being the high power operating mode; and determining the output light power as a third power in response to the operating mode of the laser being the maximum power operating mode. The third power is equivalent to a sum of the first power and the second power.

In some embodiments, the plurality of light sources with different powers may include a first light source with the first power and a second t light source with the second power. A method of driving the objective light source to emit light may include: driving the first light source to emit light in response to the operating mode of the laser being the low power operating mode; driving the second light source to emit light in response to the operating mode of the laser being the high power operating mode; and driving both of the first light source and the second light source to emit light in response to the operating mode of the laser being the maximum power operating mode.

In some embodiments, the first power is 10 W, the laser is suitable for picture engraving and printing scenarios at this power. The laser selects the first light source from the plurality of light sources with different powers as the objective light source to emit light, and the best engraving effect is capable of being achieved.

In some embodiments, the second power is 20 W, the laser is suitable for fast cutting of thin plates, precision cutting scenarios of medium thickness plates at this power. The laser selects the second light source from the plurality of light sources with different powers as the objective light source to emit light, and a requirement cutting effect is capable of being achieved.

In some embodiments, the second power is 30 W, the laser is suitable for cutting scenarios of thick plates at this power. The laser selects all of light sources to emit light, and a requirement cutting effect is capable of being achieved.

It is understandable that the above-mentioned powers of the first light source and the second light source are a feasible way to achieve, and the power of each light source is not limited in actual applications, and can be set according to the actual requirements of application scenarios.

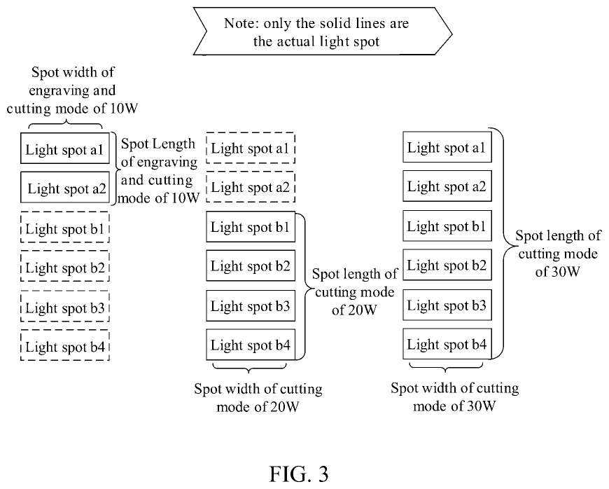

In order to facilitate understanding, a first light source group formed by two 5 W laser diodes is used as the first light source, and a second light source group formed by four 5 W laser diodes is used as the second light source as an example, combining FIG. 3 to illustrate a spot size of the laser in each operation mode. Referring to FIG. 3, shows spot sizes of the laser in three operating modes.

The first light source and the second light source are connected in parallel and can be driven independently. In the engraving and cutting mode of 10 W, since only two laser diodes of the first light source emit light, resulting in a detailed light spot, the best effect of a picture engraving imaging, small cutting slit of a thin plate and high precision. In the cutting mode of 20 W, the four laser diodes of the second light source emit light, the spot size is moderate, the output light power meets a cutting of mid-thickness materials and a rapid cutting of thin materials, and the cutting seam is moderate to ensure an accuracy of products. In the cutting mode of 30 W, a total of six laser diodes of the first light source and the second light source emit light, and the laser outputs the maximum cutting power.

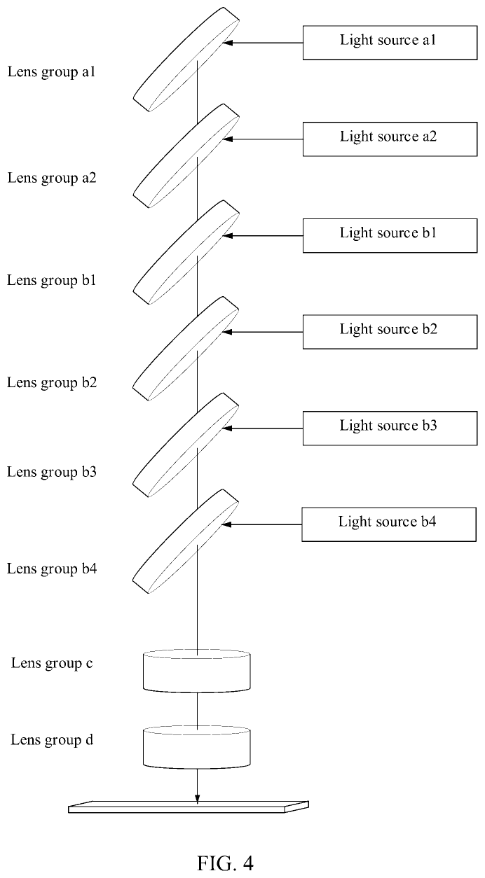

In order to facilitate understanding, the first light source includes a light source al and a light source a2, and the second light source includes a light source b1, a light source b2, a light source b3, and a light source b4 as an example. In the present embodiment, combining FIG. 4 to illustrate an operation method of a laser machine. Referring to FIG. 4, it is a schematic structural diagram of a spatial combination of the laser.
(1) LD light sources are filtrated and adjusted beam shape through a lens group a1, a2, b1, b2, b3, b4, so that only the specific wavelength light required by the module can be reflected to a light patch of vertical downward through the lens group.
(2) The laser is focused on work materials after passing through a lens group c.
(3) A Lens group d is a lens of dust-proof and flat window protection, the Lens group d is configured to prevent dusts entering the light patch to contaminate the lens.
(4) A light source module (the first light source and the second light source) will heat up significantly when working, a light source bracket is designed by metal materials to provide sufficient heat dissipation capacity, and a heat dissipation fin structure and a cooling fan and the light source bracket can be equipped to assist in heat dissipation.
(5) If all of the light sources a1, a2, b1, b2, b3, and b4 emit light, the laser is set to the maximum output light power.
(6) Each of the light sources a1, a2, b1, b2, b3, and b4 can be driven to emit light separately.
(7) In the engraving and cutting mode of 10 W, the light sources al and a2 formed a light source group of 10 W are driven to emit light, resulting in a detailed light spot, a small cutting slit, and the best effect of a picture engraving imaging. The engraving and cutting mode of 10 W is suitable for detailed line printing/engraving and thin plate cutting.
(8) In the cutting mode of 20 W, the light sources b1, b2, b3, and b4 formed a light source group of 20 W are driven to emit light, the size of light spot is moderate, which is suitable for cutting mid-thickness plates with high cutting accuracy and the rapid cutting of thin plates.
(9) In the cutting mode of 30 W, all of the light sources a1, a2, b1, b2, b3, and b4 are driven to emit light, a maximum cutting capacity of the laser is outputted.

With respect to the prior technology, the present application includes at least the following advantages: the laser is formed by the plurality of light sources with different powers, by determining the operation mode of the laser to determine the output light power corresponding to the operation mode, a laser machine is capable of setting different output light power by switching different operation modes, then the laser is capable of being applied to different scenarios, such as engraving scenarios, cutting scenarios, etc., achieving best engraving and cutting effects in different scenarios, and improving a practicality of the laser.

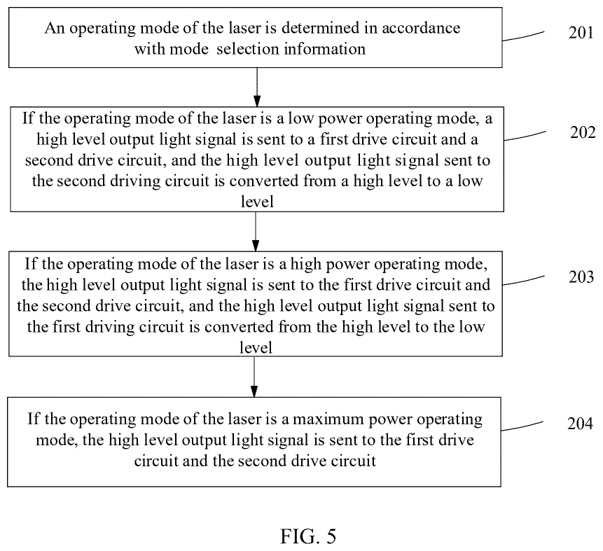

Referring to FIG. 5, it is a flowchart of a method for driving the laser according to an embodiment of the present application, the present embodiment is an explanation of the above-mentioned embodiments, specifically describe how to drive different light sources to emit light. The laser further includes a first drive circuit and a second drive circuit, the first drive circuit drives the first light source to emit light when receiving a high level output light signal, and the second drive circuit drives the second light source to emit light when receiving the high level output light signal.

The present embodiment is applied to the laser side, as shown in FIG. 5, the method includes the following blocks:

In block 201, an operating mode of the laser is determined according to mode selection information.

In block 202, if the operating mode of the laser is a low power operating mode, a high level output light signal is sent to a first drive circuit and a second drive circuit, and the high level output light signal sent to the second driving circuit is converted from a high level to a low level.

In some embodiments, the high level and the low level of the output light signal sent to the drive circuits can be adjusted by controlling a transistor to turn on or off.

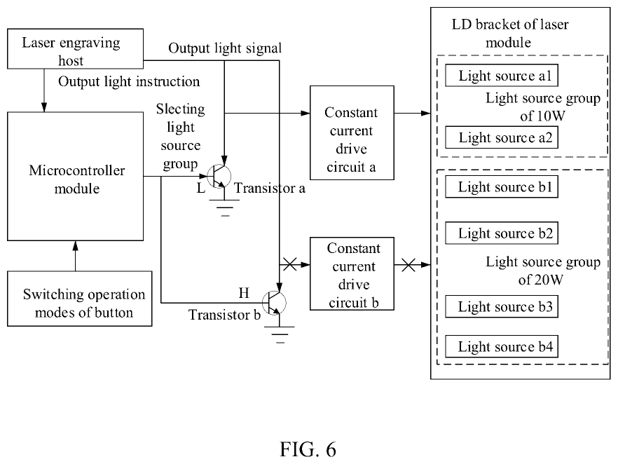

In order to facilitate understanding, the first light source is a light source group of 10 W and the second light source is a light source group of 20 W as an example, and combining FIG. 6 to illustrate a driving method of the laser in the low-power operation mode of the present embodiment. As shown in FIG. 6, it is a schematic diagram of the driving method of the laser in the low-power operation mode.
(1) A laser engraving host sends an output light instruction and an output light signal to the laser module (the first light source and the second light source). The laser module starts working in response to receiving the output light instruction, otherwise the laser module will not work.
(2) The output light signal is a pulse width modulation (PWM) signal, a duty cycle of the PWM signal is proportional to the current output light power required by the laser.
(3) The transistor is a negative-positive-negative (NPN) transistor, and a microcontroller module raises a base voltage of the transistor, the transistor is turned on to pull the output light signal into the low level.
(4) Constant current drive circuits a and b drives corresponding light source groups to emit light in response to receiving the output signal of high-level.
(5) In the engraving and cutting mode of 10 W, the microcontroller module raises a base voltage of a transistor b, the transistor b is turned on, a signal b is converted from the high level to the low level, and the light source group of 20 W does not work. A base electrode of a transistor a is pulled low and not conducting, and a signal a is normally inputted into the constant current drive circuit a, the light source group of 10 W is driven to emit light.

In some embodiment, the present application does not limit to using the transistor, other structures can be used to control the conversion of the output light signal sent to the drive circuit from the high level to the low level, such as a switch can be used to convert signal level, etc., the present embodiment does not limit the structure to achieve the conversion of the output light signal sent to the drive circuit from the high level to the low level.

In block 203, if the operating mode of the laser is a high power operating mode, the high level output light signal is sent to the first drive circuit and the second drive circuit, and the high level output light signal sent to the first driving circuit is converted from the high level to the low level.

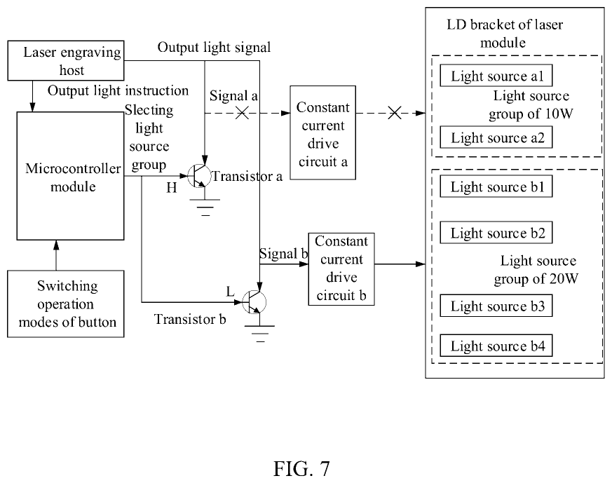

In order to facilitate understanding, the first light source is a light source group of 10 W and the second light source is a light source group of 20 W as an example, and combining FIG. 7 to illustrate a driving method of the laser in the high-power operation mode of the present embodiment. As shown in FIG. 7, it is a schematic diagram of the driving method of the laser in the high-power operation mode.

In the cutting mode of 20 W, the microcontroller module raises a base voltage of the transistor a, the transistor a is turned on, a signal a is converted from the high level to the low level, and the light source group of 10 W does not work. A base electrode of the transistor b is pulled low and not conducting, and a signal b is normally inputted into the constant current drive circuit b, the light source group of 20 W is driven to emit light.

In block 204, if the operating mode of the laser is a maximum power operating mode, the high level output light signal is sent to the first drive circuit and the second drive circuit.

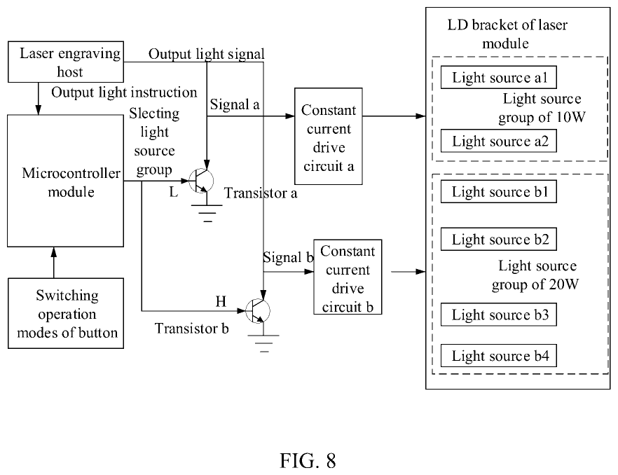

In order to facilitate understanding, the first light source is a light source group of 10 W and the second light source is a light source group of 20 W as an example, and combining FIG. 8 to illustrate a driving method of the laser in the maximum-power operation mode of the present embodiment. As shown in FIG. 8, it is a schematic diagram of the driving method of the laser in the maximum-power operation mode.

In the cutting mode of 30 W, the microcontroller module raises base voltages of the transistor a and the transistor b, the transistor a and the transistor b are turned off, a signal a is normally inputted into the constant current drive circuit a and a signal b is normally inputted into the constant current drive circuit b, both of the light source group of 10 W and the light source group of 20 W are driven to emit light.

With respect to the prior technology, the present application includes at least the following advantages: the laser is formed by the plurality of light sources with different powers, by determining the operation mode of the laser to determine the output light power corresponding to the operation mode, a laser machine is capable of setting different output light power by switching different operation modes, then the laser is capable of being applied to different scenarios, such as engraving scenarios, cutting scenarios, etc., achieving best engraving and cutting effects in different scenarios, and improving a practicality of the laser.

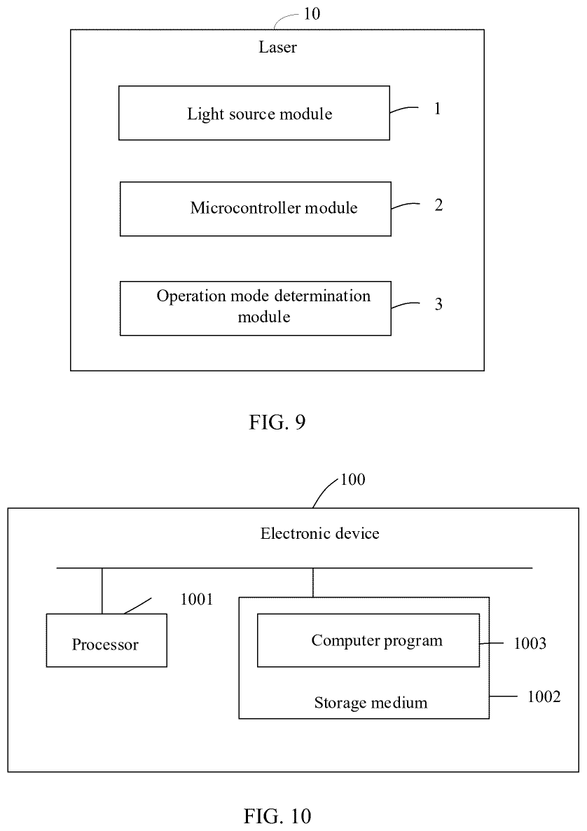

Referring to FIG. 9, it is a schematic module diagram of the laser according to an embodiment of the present application. As shown in FIG. 9, the laser includes a light source module 1, a microcontroller module 2, and an operation mode determination module 3. The light source module 1 includes a plurality of light sources with different powers. The operation mode determination module 3 is configured to determine an operating mode of the laser according to mode selection information. The microcontroller module 2 is configured to determine an output light power corresponding to the operating mode of the laser, select an objective light source with the same power as the output light power from the light source module 1, and drive the objective light source to emit light.

Referring to FIG. 10, it is a schematic structural diagram of an electronic device 100 according to an embodiment of the present application. As shown in FIG. 10, the electronic device 100 may include a processor 1001, and a data storage 1002. The data storage 1002 is configured to store one or more computer programs 1003. The one or more computer programs 1003 are configured to be executed by the processor 1001. The one or more computer programs 1003 include instructions, and the instructions is capable of being executed by the electronic device 100 to implement the method for driving the laser.

It can be understood that the structure shown in this embodiment does not constitute a limitation on the electronic device 100. In other embodiments, the electronic device 100 may include more or fewer components than shown in FIG. 10, or combine some components, or separate some components, or arrange different components.

The processor 1001 may include one or more processing units, for example, the processor 1001 may include an application processor (AP), a modem, a graphics processing unit (GPU), an image signal processor (ISP), a controller, a video codec, a digital signal processor (DSP), a baseband processor, and/or a neural network processing unit (NPU), etc. Different processing units may be independent components, or may be integrated in one or more processors.

A memory may also be integrated in the processor 1001 for storing instructions and data. In some embodiments, the memory integrated in processor 1001 is a cache memory. The memory may store instructions or data that the processor 1001 has just used or recycled. If the processor 1001 needs to use the instruction or data again, it can be directly recalled from the memory, and a repeated store and read is avoided. A waiting time of the processor 1001 is reduced, and an efficiency of the system is improved.

In some embodiment, the processor 1001 may include one or more interfaces. The interfaces may include an inter-integrated circuit (I2C) interface, an inter-integrated circuit sound (I2S) interface, a pulse code modulation (PCM) interface, a universal asynchronous receiver/transmitter (UART) interface, a mobile industry processor interface (MIPI), a general-purpose input/output (GPIO) interface, a subscriber identity module (SIM) interface, and/or a universal serial bus (USB) interface, etc.

In some embodiment, the data storage 1002 may include a high-speed random access memory, and may also include a non-volatile memory, such as a hard disk, an internal memory, a plug-in hard disk, a smart media card (SMC), a secure digital (SD) card, a flash card, at least one magnetic disk memory, a flash memory, or other non-volatile solid-state memory.

The present application further provides a computer storage medium, the computer storage medium stores computer instructions, when the computer instructions run on an electronic device, the electronic device is caused to execute the above-mentioned method for driving the laser.

The electronic device and the computer storage medium in this embodiment are used to execute the above-mentioned method, so beneficial effects that is capable of being achieved can be referred to beneficial effects of the above-mentioned method, which will not be repeated herein.

In practical applications, the above-mentioned functions can be allocated to different functional modules to complete according to actual requirements. That is, an internal structure of a device is divided into different functional modules to complete all or part of the above-mentioned functions.

In the several embodiments provided in this application, it should be understood that the disclosed devices and methods may be implemented in other ways. For example, the device embodiments described above are only illustrative. For example, the division of the modules or units is only a logical function division. In an actual implementation, there may include other division ways. For example, a plurality of units or components can be combined or can be integrated into another device, or some features can be omitted, or not be implemented. In the other hand, the coupling or direct coupling or communication connection shown or discussed may be through some interfaces, and the indirect coupling or communication connection of devices or units may be in electrical, mechanical or other forms.

The unit described as a separate component may or may not be physically separated, and a component displayed as a unit may be one physical unit or a plurality of physical units. That is, it may be located in one place, or may be distributed to a plurality of different places. Part or all of the units can be selected according to actual requirements to achieve the purpose of the solution of this embodiment.

In addition, functional units in each embodiment of the present application may be integrated into one processing unit, each functional unit may also exist separately and physically, or two or more units may be integrated into one unit. The above-mentioned integrated units can be implemented in a form of hardware or in a form of software functional units.

If the integrated units are realized in the form of software function units and sold or used as an independent product, the integrated units can be stored in a readable storage medium. Based on this understanding, the technical solution of the embodiment of the present application is essentially or the part that contributes to the prior art, or all or part of the technical solution can be embodied in the form of a software product, and the software product is stored in a storage medium. The software product includes several instructions to make a device (may be a single-chip microcomputer, a chip, etc.) or a processor execute all or part of steps of the methods described in the various embodiments of the present application. The storage medium may include: a USB flash disk, a mobile hard disk, a read-only memory (ROM), a random access memory (RAM), a magnetic disk, an optical disk, and other various media that can store program codes.

The above is only a specific implementation of the present application, a protection scope of the present application is not limited thereto, and any changes or replacements within the technical scope disclosed in the present application should be covered within the protection scope of the present application.

1. A method for driving a laser, wherein the laser is provided with a plurality of light sources with different powers, the method comprises:
determining an operating mode of the laser in accordance with mode selection information;
determining an output light power corresponding to the operating mode of the laser, and selecting one or more objective light sources from the plurality of light sources in accordance with the output light power corresponding to the operating mode of the laser, wherein a sum of output light powers of the one or more objective light sources is equal to the output light power corresponding to the operating mode of the laser; and
driving the one or more objective light sources to emit light.

2. The method as claimed in claim 1, wherein the operating mode of the laser is provided with a low power operating mode, a high power operation mode, and a maximum power operation mode, determining the output light power corresponding to the operating mode of the laser further comprises:
determining the output light power as a first power in response to the operating mode of the laser being the low power operating mode;
determining the output light power as a second power in response to the operating mode of the laser being the high power operating mode; and
determining the output light power as a third power in response to the operating mode of the laser being the maximum power operating mode,
wherein the first power is less than the second power and the third power is equivalent to a sum of the first power and the second power.

3. The method as claimed in claim 2, wherein the plurality of light sources are provided with a first light source with the first power and a second light source with the second power, driving the one or more objective light sources to emit light further comprises:
driving the first light source to emit light in response to the operating mode of the laser being the low power operating mode;
driving the second light source to emit light in response to the operating mode of the laser being the high power operating mode; and
driving the first light source and the second light source to emit light in response to the operating mode of the laser being the maximum power operating mode.

4. The method as claimed in claim 3, wherein the laser is further provided with a first driving circuit and a second driving circuit, the first driving circuit drives the first light source to emit light when receiving a high level output light signal, and the second driving circuit drives the second light source to emit light when receiving the high level output light signal; driving the first light source to emit light in response to the operating mode of the laser being the low power operating mode further comprises:
sending the high level output light signal to the first drive circuit and the second drive circuit in response to the operating mode of the laser being the low power operating mode; and
converting the high level output light signal sent to the second driving circuit from a high level to a low level.

5. The method as claimed in claim 4, wherein driving the second light source to emit light in response to the operating mode of the laser being the high power operating mode further comprises:
sending the high level output light signal to the first drive circuit and the second drive circuit in response to the operating mode of the laser being the high power operating mode; and
converting the high level output light signal sent to the first driving circuit from the high level to the low level.

6. The method as claimed in claim 4, wherein driving the first light source and the second light source to emit light in response to the operating mode of the laser being the maximum power operating mode further comprises:
sending the high level output light signal to the first drive circuit and the second drive circuit in response to the operating mode of the laser being the maximum power operating mode.

7. The method as claimed in claim 1, wherein determining the operating mode of the laser in accordance with the mode selection information further comprises:
determining the operating mode of the laser in accordance with key operation information of a user.

8. (canceled)

9. A non-transitory computer storage medium comprising computer instructions, wherein when the computer instructions run on an electronic device, the electronic device is caused to execute a method for driving a laser, the laser is provided with a plurality of light sources with different powers, the method comprises:
determining an operating mode of the laser in accordance with mode selection information;
determining an output light power corresponding to the operating mode of the laser, and selecting one or more objective light sources from the plurality of light sources in accordance with the output light power corresponding to the operating mode of the laser, wherein a sum of output light powers of the one or more objective light sources is equal to the output light power corresponding to the operating mode of the laser; and
driving the one or more objective light sources to emit light.

10. An electronic device comprising a processor and a non-transitory storage medium, wherein the non-transitory storage medium is configured to store instructions, the processor is configured to call the instructions stored in the non-transitory storage medium, to cause the electronic device to execute a method for driving a laser, the laser is provided with a plurality of light sources with different powers, the method comprises:
determining an operating mode of the laser in accordance with mode selection information;
determining an output light power corresponding to the operating mode of the laser, and selecting one or more objective light sources from the plurality of light sources in accordance with the output light power corresponding to the operating mode of the laser, wherein a sum of output light powers of the one or more objective light sources is equal to the output light power corresponding to the operating mode of the laser; and
driving the one or more objective light sources to emit light.

11. The electronic device as claimed in claim 10, wherein the operating mode of the laser is provided with a low power operating mode, a high power operation mode, and a maximum power operation mode, determining the output light power corresponding to the operating mode of the laser further comprises:
determining the output light power as a first power in response to the operating mode of the laser being the low power operating mode;
determining the output light power as a second power in response to the operating mode of the laser being the high power operating mode; and
determining the output light power as a third power in response to the operating mode of the laser being the maximum power operating mode,
wherein the first power is less than the second power and the third power is equivalent to a sum of the first power and the second power.

12. The electronic device as claimed in claim 11, wherein the plurality of light sources are provided with a first light source with the first power and a second light source with the second power, driving the one or more objective light sources to emit light further comprises:
driving the first light source to emit light in response to the operating mode of the laser being the low power operating mode;
driving the second light source to emit light in response to the operating mode of the laser being the high power operating mode; and
driving the first light source and the second light source to emit light in response to the operating mode of the laser being the maximum power operating mode.

13. The electronic device as claimed in claim 12, wherein the laser is further provided with a first driving circuit and a second driving circuit, the first driving circuit drives the first light source to emit light when receiving a high level output light signal, and the second driving circuit drives the second light source to emit light when receiving the high level output light signal;
driving the first light source to emit light in response to the operating mode of the laser being the low power operating mode further comprise:
sending the high level output light signal to the first drive circuit and the second drive circuit in response to the operating mode of the laser being the low power operating mode; and
converting the high level output light signal sent to the second driving circuit from a high level to a low level.

14. The electronic device as claimed in claim 13, wherein driving the second light source to emit light in response to the operating mode of the laser being the high power operating mode further comprises:
sending the high level output light signal to the first drive circuit and the second drive circuit in response to the operating mode of the laser being the high power operating mode; and
converting the high level output light signal sent to the first driving circuit from the high level to the low level.

15. The electronic device as claimed in claim 13, wherein driving the first light source and the second light source to emit light in response to the operating mode of the laser being the maximum power operating mode further comprises:
sending the high level output light signal to the first drive circuit and the second drive circuit in response to the operating mode of the laser being the maximum power operating mode.

16. The electronic device as claimed in claim 10, wherein determining the operating mode of the laser in accordance with the mode selection information further comprises:
determining the operating mode of the laser in accordance with key operation information of a user.
